(19) United States
(12) Patent Application Publication
(10) Pub. No.: US 2012/0055707 A1
(43) Pub. Date: Mar. 8, 2012

(54) Use of Aliphatic Hydrocarbons and Paraffins as Solvents for Silver Sinter Pastes

(75) Inventors: Michael SCHÄFER, Kunzell (DE); Wolfgang SCHMITT, Rodgau (DE)

(73) Assignee: HERAEUS MATERIALS TECHNOLOGY GMBH & CO. KG, Hanau (DE)

(21) Appl. No.: 13/224,478

(22) Filed: Sep. 2, 2011

(30) Foreign Application Priority Data
Sep. 3, 2010 (DE) 10 2010 044 326.3

(51) Int. Cl. H05K 1/18; B23K 31/02; C09J 191/00

(52) U.S. Cl. 174/260; 106/243; 228/180.22

(57) ABSTRACT

A process is provided for fastening an electronic component to a substrate, the process including the steps of: (i) providing an electronic component and a substrate; (ii) creating a sandwich arrangement having the electronic component, the substrate and a layer arranged in between them, wherein the layer includes a paste containing (a) metal particles having a coating including at least one coating compound selected from the group consisting of fatty acids, fatty acid salts and fatty acid esters, and (b) at least one aliphatic hydrocarbon compound; and (iii) sintering the sandwich arrangement.

### BACKGROUND OF THE INVENTION

The present invention relates to a method for fastening an electronic component on a substrate as well as a paste that can be used in this method.

In the field of power electronics the connection of substrates with components, such as LEDs or very thin silicon chips which have a very high pressure and temperature sensitivity, presents a special challenge.

For this reason substrates are frequently bonded with such pressure and temperature-sensitive components by adhesive bonding. Appropriate conductive adhesives usually contain silver particles, thermosetting polymers and reactive diluents. However, adhesive bonding technology has the disadvantage that this creates contact points between the substrate and component, which only have an insufficient heat conductivity and electrical conductivity.

In order to solve this problem, it was proposed to bond substrates and electronic components with one another by sintering.

However, conventional sintering processes require either a high process pressure or a high process temperature. These prerequisites often lead to damaging of the components to be bonded, so that conventional sintering processes are excluded for many applications.

German published patent application DE 10 2007 046 901 A1 proposes a sintering technique which makes it possible to build very good electrically conducting and thermoconducting compound layers for power electronics. This sintering processes uses a metallic paste, which contains a silver compound in addition to an alcoholic solvent, that disintegrates to elementary silver below 300° C. These metallic pastes make it possible to reduce the process pressure to less than 3 bar and reduce the process temperature to below 250° C. This sintering technique represents an enormous quality leap in the bonding of substrates with pressure and temperature-sensitive components.

Nevertheless, it would be desirable for many applications if the process temperature could be lowered even further without having to take any impairments into account with respect to the shearing resistance of the developing contact points. This would cause less stress of the components to be bonded and thereby a further quality improvement of component parts in the field of power electronics. Furthermore, it would be possible to considerably save on energy costs if the process temperature could be lowered even more.

The prior art processes for fastening electronic components on substrates have room for improvement in another respect. It is for example possible in particular cases to generate a contact layer between an electronic component and a substrate, which has a high shearing resistance. To be sure, in mass production as a rule the problem arises that this shearing resistance strongly varies from contact layer to contact layer. Therefore, it has been impossible up to now to generate contact layers between electronic components and substrates with uniform quality with respect to the shearing resistance of the contact points.

### BRIEF SUMMARY OF THE INVENTION

The present invention is therefore based on the object of providing a sintering process which allows for an electronic component to be bonded with a substrate in a stable manner, wherein the process temperature is below 250° C. Contact points should thereby be created with uniform quality between the substrate and the component to be bonded, which have a high shearing resistance, a low porosity and a high electrical and thermal conductivity.

An additional object of the present invention is to provide a paste that can be used in the sintering process according to the invention.

These objects are achieved by the present invention, which provides a process for fastening an electronic component with a substrate, in which one
(i) provides an electronic component and a substrate,
(ii) creates a sandwich arrangement, which has the electronic component, the substrate and a layer located in between which includes a paste, the paste containing (a) metal particles having a coating, which contains at least one compound selected from the group consisting of fatty acids, fatty acid salts and fatty acid esters, and (b) at least one aliphatic hydrocarbon compound, and
(iii) sinters the sandwich arrangement.

Furthermore, the invention makes available a paste containing (a) metal particles, which have a coating, which contains at least one compound selected from the group consisting of fatty acids, fatty acid salts and fatty acid esters, and (b) at least one aliphatic hydrocarbon compound.

The prior art pastes usually contain metal particles which are coated to avoid agglomeration of the metal particles in the paste. Silicon dioxide, metal oxide, metal alloys, polymers or fatty acids, for example, are used as coating compounds. These coating compounds make it possible to effectively avoid an agglomeration. However, the sintering process has the disadvantage that these coating compounds considerably slow down the diffusion speed and, consequently, make necessary high process temperatures. Hence, the sintering step can only take place after the coating compounds have been burnt off and the surfaces of the metal particles have been exposed.

The invention is based on the surprising recognition that the sintering temperatures can be reduced considerably when the metal particles contained in the paste have a coating made of fatty acids (or a fatty acid derivative) and the pastes additionally contain aliphatic hydrocarbons.

Without wanting to be bound to one theory, the aliphatic hydrocarbon compounds appear to be able to promote burning off fatty acids from the metal particles at temperatures of less than 250° C. It is presumed that, at temperatures of less than 250° C., the aliphatic hydrocarbon compounds are introduced between the surface of the metal particles and the fatty acid layer above it, so that the fatty acids are surrounded by and partially dissolved by the aliphatic hydrocarbons. Although this process does not show any disadvantageous effects with respect to a hindrance of agglomerating the metal particles, this obviously leads to a burning off of the fatty acids at temperatures below 250° C., so that the surfaces of the metal particles are already available at these temperatures for the sintering process. Furthermore, contact layers are created in this sintering process between the electronic component and the substrate, which have a high shearing resistance as well as a uniform and reproducible quality with respect to the shearing resistance. Furthermore, the use of the aliphatic hydrocarbon compounds allows for achieving a more homogeneous distribution of the components of the pastes, than is the case for pastes containing conventional solvents. This results, among other things, in a better processability of the pastes according to the invention relative to the prior art pastes.

### DETAILED DESCRIPTION OF THE INVENTION

The paste used according to the invention contains metal particles.

In the context of the invention, the term metal refers to an element that can be found in the Periodic Table of the elements in the same period as boron, but to the left of boron, in the same period as silicon, but to the left of silicon, in the same period as germanium, but to the left of germanium, and in the same period as antimony, but to the left of antimony, as well as to all elements that have a higher atomic number than 55. According to the invention, the term “metal” also includes alloys and intermetallic phases.

The metal preferably has a purity of at least 95 weight percent, preferably at least 98 weight percent, more preferably at least 99 weight percent, and even more preferably at least 99.9 weight percent.

According to a preferred embodiment, the metal is selected from the group consisting of copper, silver, nickel, and aluminum. According to a most preferred embodiment, the metal is silver.

The metal particles contained in the paste can be homogeneous or heterogeneous with respect to their composition. In particular, the particles in the paste can contain different metals.

The metal particles can be of a varying form. The metal particles can, for example, be in the form of flakes or of a spherical (ball-shaped) form. According to a particularly preferred embodiment, the metal particles have the form of flakes. However, this does not exclude a minor quantity of the metal particles used can also having a different form. However, it is preferred that at least 70 weight percent, more preferably at least 80 weight percent, even more preferably at least 90 weight percent or 100 weight percent of the particles be in the form of flakes.

According to the invention the metal particles are coated.

According to the invention, a coating of particles is understood to be an adhering layer on the surface of particles. According to the invention, adhering layer means that the layer does not separate gravitationally from the metal particles.

According to the invention, the coating of the metal particles contains at least one coating compound.

This at least one coating compound includes a compound selected from the group consisting of fatty acids, fatty acid salts and fatty acid esters. These coating compounds should avoid an agglomeration of the metal particles contained in the paste and contribute to the stabilization of the paste.

The coating compounds are preferably selected from the group consisting of saturated compounds, monounsaturated compounds, polyunsaturated compounds, and mixtures thereof

Furthermore, the coating compounds are preferably selected from the group consisting of branched compounds, unbranched compounds and mixtures thereof.

The coating compounds preferably have 8-28, even more preferably 12-24 and particularly preferably 12-18 carbon atoms.

According to a preferred embodiment, the coating compounds include mono fatty acids, salts from mono fatty acids or mono fatty acid esters.

As fatty acid salts, salts are preferably considered, whose anionic components constitute the deprotonated fatty acids, and whose cationic components are selected from the group consisting of ammonium ions, monoalkylammonium ions, dialkylammonium ions, trialkylammonium ions, lithium ions, sodium ions, potassium ions, copper ions, and aluminum ions.

Preferred fatty acid esters are derived from the corresponding fatty acids, wherein the hydroxyl groups of the acid units are replaced by alkyl groups, particularly methyl groups, ethyl groups, propyl groups, or butyl groups.

According to a preferred embodiment, the at least one coating compound is selected from the group consisting of caprylic acids (octanoic acids), capric acids (decanoic acids), lauric acids (dodecanoic acids), myristic acids (tetradecanoic acids), palmitic acids (hexadecanoic acids), stearic acids (octadecanoic acids), mixtures thereof, as well as the corresponding esters and salts and mixtures thereof.

According to a particularly preferred embodiment, the at least one coating compound is selected from the group consisting of lauric acids (dodecanoic acids), stearic acids (octadecanoic acids), sodium stearate, potassium stearate, aluminium stearate, copper stearate, sodium palmitate, and potassium palmitate.

The metal particles used according to the invention can be obtained commercially. The corresponding coating compounds are applied on the surface of the metal particle by conventional and known prior art processes.

It is for example possible to suspend the coating compounds, particularly the previously mentioned stearates or palmitates, in solvents and to grind the suspended coating compounds with metal particles in ball mills. After grinding the metal particles, now coated with the coating compounds, are dried and subsequently freed from dust.

The portion of the at least one coating compound, selected from the group consisting of fatty acids, fatty acid salts and fatty acid esters, is preferably at least 80 weight percent, more preferably at least 90 weight percent, particularly preferably at least 95 percent, most particularly preferably at least 99 weight percent, and particularly 100 weight percent relative to the total weight of the coating.

According to a preferred embodiment, the portion of the coating compounds is 0.05-3 weight percent, more preferably 0.07-2.5 weight percent and even more preferably 0.1-2.2 weight percent, relative to the weight of the coated metal particles.

The coating grade, which is defined as the relationship of the mass of coating compounds to the surface of the metal particles, is preferably 0.00005-0.03 g, more preferably 0.0001-0.02 g and even more preferably 0.0005-0.02 g of coating compounds per square meter (m²) of surface of metal particles.

According to the invention, the paste contains at least one aliphatic hydrocarbon compound.

According to the invention, aliphatic hydrocarbon compounds are understood to be compounds composed of carbon atoms and hydrogen atoms and are not aromatic. Consequently, the aliphatic hydrocarbon compounds according to the invention do not contain heteroatoms.

The at least one aliphatic hydrocarbon compound appears to be able to promote the burning off of fatty acids or fatty acid derivatives contained on the metal particles as coating compounds at temperatures of below 250° C., so that the reactive surfaces of the metal particle are already available for the sintering process at lower temperatures. As a result, a distinct lowering of the sintering temperature can be achieved.

Furthermore, the at least one aliphatic hydrocarbon compound can serve as solvent substitute and effectively eliminate water retention based on its non-polar nature.

The at least one aliphatic hydrocarbon compound is preferably selected from the group consisting of saturated compounds, monounsaturated compounds, polyunsaturated compounds and mixtures thereof. According to a particularly preferred embodiment, the aliphatic hydrocarbon compound is selected from the group consisting of saturated aliphatic hydrocarbon compounds.

Furthermore, the at least one aliphatic hydrocarbon compound can be a cyclic or acyclic compound.

According to a preferred embodiment, the at least one aliphatic hydrocarbon compound is selected from the group consisting of n-alkanes, isoalkanes, cycloalkanes, and mixtures thereof.

The at least one aliphatic hydrocarbon compound used according to the invention preferably has 5-32 carbon atoms, more preferably 10-25 carbon atoms and even more preferably 16-20 carbon atoms.

According to a preferred embodiment, the aliphatic hydrocarbon compound is selected from the group consisting of saturated hydrocarbons, which are represented by the formulas CₙH₂ₙ₊₂, CₙH₂ₙ and CₙH₂ₙ₋₂, wherein n stands for a whole number between 5 and 32, preferably between 10 and 25 and more preferably between 16 and 20.

According to a most preferred embodiment, the at least one aliphatic hydrocarbon compound is selected from the group consisting of hexadecane, octadecane, isohexadecanes, isooctadecanes, cyclohexadecanes, and cyclooctadecanes. For example, the at least one aliphatic hydrocarbon compound can be a mixture of aliphatic hydrocarbon compounds as distributed for example by Exxon Mobil under the brand name of Exxsol™ D140 or under the brand name Isopar M™.

The paste according to the invention preferably contains 75-90 weight percent, more preferably 77-89 weight percent and even more preferably 80-88 weight percent of metal particles relative to the total weight of the paste.

According to a preferred embodiment, the paste contains 0.05-2.5 weight percent, more preferably 0.07-2.2 weight percent and even more preferably 0.1-2 weight percent of the at least one coating compound selected from the group consisting of fatty acids, fatty acid salts and fatty acid esters, relative to the total weight of the paste.

The portion of the at least one aliphatic hydrocarbon compound in the paste is not particularly restricted. In order to achieve a good processability of the paste, it can be advantageous that the paste contain 3-25 weight percent, more preferably 4-20 weight percent and even more preferably 5-18 weight percent of the at least one aliphatic hydrocarbon compound, relative to the total weight of the paste.

It has also proven to be particularly advantageous to provide a quantity of the at least one aliphatic hydrocarbon compound in the paste, which is large enough to allow a simple burning off of the coating compounds at temperatures below 250° C. Accordingly, the ratio of the weight proportion of the coating compounds to the weight proportion of the at least one aliphatic hydrocarbon compound is at maximum 0.1%.

On the other hand, the quantity of aliphatic hydrocarbons should also not be selected particularly high relative to the quantity of coating compounds, so that the effects according to the invention can be obtained. According to a particularly preferred embodiment, the ratio of the weight proportion of coating compounds to the weight proportion of the at least one aliphatic hydrocarbon compound is thus in the range of 0.001-1.0, more preferably in the range of 0.005-0.85 and even more preferably in the range of 0.01-0.7.

According to an additional preferred embodiment, the molar ratio of the main component of the coating, selected from the group consisting of fatty acids, fatty acid salts and fatty acid esters, to the main component of the at least one aliphatic hydrocarbon compound is in the range of 0.001-1.0, more preferably in the range of 0.005-0.85 and even more preferably in the range of 0.01-0.7. The molar ratio in the framework of the invention refers to the ratio of quantities of material of the respective elements in the paste. According to the invention, the main component of the coating is formed of the coating compound selected from the group consisting of fatty acids, fatty acid salts and fatty acid esters, which is present in a larger quantity than optionally other contained coating compounds than those selected from the group consisting of fatty acids, fatty acid salts and fatty acid esters. According to the invention, the main component of the at least one aliphatic hydrocarbon compound is formed from the aliphatic hydrocarbon compound, which is present in a larger quantity than optionally other contained aliphatic hydrocarbon compounds.

It was surprisingly determined that the lowering of the sintering temperature, which is strived for according to the invention, is linked on the one hand to the length of the main chain of the fatty acid or of the fatty acid derivative, which is primarily contained in the coating of metal particle, and is on the other hand linked to the main chain of the aliphatic hydrocarbon compound, which represents the at least one aliphatic hydrocarbon compound or the principal components of the mixture from the aliphatic hydrocarbon compounds. It was thus found that a particularly strong lowering of the sintering temperature can be achieved, if the main chains of this fatty acid or this fatty acid derivative and of this aliphatic hydrocarbon compound have the same or a similar number of carbon atoms.

According to a most particularly preferred embodiment, the ratio of the carbon atoms, which are contained in the main chain of the main component of the coating, to the carbon atoms, which are contained in the main chain of the main component of at least the aliphatic hydrocarbon compound, thus lies in the range of 0.5-2.0, more preferably in the range of 0.6-1.4, even more preferably in the range of 0.8-1.2 and most particularly preferably in the range of 0.85-1.15.

If the metal particles have, for example, a coating that contains a mixture of 20 weight percent lauric acid (a fatty acid having a main chain of 12 carbon atoms), 35 weight percent myristic acid (a fatty acid having a main chain of 14 carbon atoms) and 45 weight percent potassium stearate (a salt of a fatty acid having a main chain of 18 carbon atoms), the potassium stearate is thus the main component of the coating. In this case, an extraordinary lowering of the sintering temperature can be achieved, if the single aliphatic hydrocarbon compound or the main component of a mixture of aliphatic hydrocarbon compounds has a main chain with a similar or identical number of carbon atoms. It would thus be preferable if the single aliphatic hydrocarbon compound or the main component of a mixture of aliphatic hydrocarbon compounds is a main chain with 16-20 carbon atoms, particularly with 18 carbon atoms.

The paste according to the invention can contain other substances in addition to the aforementioned components.

According to a preferred embodiment, the paste contains at least one metal precursor.

In the context of the invention, a metal precursor refers to a compound, which is decomposed to the metal of the metal precursor at temperatures of below 250° C. in the presence of the metal particles contained in the paste. A metal is thus preferably formed in situ when using a metal precursor during the sintering process. It can be simply determined whether the compound relates to a metal precursor according this preferred embodiment. A paste, which contains a compound to be tested, can for example be deposited on a substrate having a silver surface, heated to 250° C. and left at this temperature for 20 minutes. Afterwards, it is examined whether under these conditions the compound to be tested has decomposed to a metal. To that end, the content of the metal-containing paste components can be weighed prior to the test, and the theoretical mass of the metal can be calculated therefrom. After the test the mass of the material deposited on the substrate can be determined gravimetrically. If the mass of the material deposited on the substrate corresponds with the theoretical mass of the metal, wherein the usual measurement deviations are to be taken into account, the tested compound is a metal precursor according to this preferred embodiment.

According to a further preferred embodiment, the metal precursor has a metal that is also contained in the metal particles. According to a particularly preferred embodiment, the metal precursor therefor has silver or copper as metal.

It can be preferred to use as metal precursor metal carbonate, metal lactate, metal formate, metal citrate. metal oxide, or metal fatty acid salts, preferably fatty acid salts having 6 to 24 carbon atoms.

Silver carbonate, silver lactate, silver formate, silver citrate, silver oxide (for example AgO or Ag₂O), copper lactate, copper stearate, copper oxide (for example Cu₂O or CuO), gold oxide (for example Au₂O or AuO), or mixtures thereof are used as metal precursor in particular embodiments.

According to a particularly preferred embodiment, the metal precursor is selected from the group consisting of silver carbonate and silver oxides.

If present, the metal precursor exists in the paste preferably in particulate form, particularly preferably in the form of flakes.

The use of a metal precursor, which releases metal in situ during the sintering process, results in the metal formed in situ during the sintering process closing up holes between the metal particles contained in the paste. In this manner, the porosity of a contact point between two components to be bonded can be reduced.

The paste can also contain at least one sintering aid. This sintering aid is preferably able to ensure a burning off of coating compounds below 250° C. during the sintering process at temperatures below 250° C., to thus make it possible to sinter at temperatures below 250° C. Particularly suitable sintering aids ensure a burning off the coating compounds at temperatures below 250° C., either directly or indirectly through intermediately formed compounds.

According to a preferred embodiment the sintering aid can be an oxidizing agent. By oxidizing agent is to be understood a substance that can oxidize other substances and is thereby reduced itself. An oxidizing agent can take up electrons and is thus an electron acceptor. The sintering aid is preferably also an oxygen carrier. This means a substance that can give off oxygen. According to this embodiment, (i) organic peroxide (such as cumylperoxide), (ii) inorganic peroxide and (iii) inorganic acids, for example, can be used as sintering aids. These compounds can serve as sintering aids, since these contain at least one oxygen atom and make possible a burning of the coating compounds, which are present on the metal particles of the paste, at a temperature of below 250° C.

According to a further preferred embodiment, the sintering aid can also ensure that the metal oxides, which can be present on the surface of the metal particle contained in the paste and can interfere with the sintering process, are reduced. For this reason, compounds can be used as sintering aids, which release a reducing agent in the course of the sintering process. This reducing agent is preferably carbon monoxide. According to this embodiment, the sintering aid can, for example, be selected from the group consisting of (iv) salts of organic acids, wherein the organic acids have 1-4 carbon atoms (such as aluminum formate), (v) esters of organic acids, wherein the organic acids have 1-4 carbon atoms, and (vi) carbonyl complexes. These compounds can serve as sintering aids, in that these release carbon monoxide during the sintering process or are involved in the release of carbon monoxide and thus allow for a reduction of the metal oxide, which are contained on the surface of the metal particle contained in the metal paste, to the corresponding metal at a temperature of below 250° C.

In addition to the aliphatic hydrocarbon compound, the paste can contain further compounds, which can work as solvent. The solvents usually used for metal pastes come into consideration for this. For example, the following can be used as solvents: α-terpineol ((R)-(+)-α-terpineol, (S)-(−)-α-terpineol or racemate), β-terpineol, γ-terpineol, δ-terpineol, mixtures of the aforementioned terpineols, N-methyl-2-pyrrolidone, ethyleneglycol, dimethylacetamide, 1-tridecanol, 2-tridecanol, 3-tridecanol, 4-tridecanol, 5-tridecanol, 6-tridecanol, isotridecanol, dibasic esters (preferably dimethylesters of the glutar-, adipin- or Bernstein acids or mixtures thereof), glycerin, diethyleneglycol, triethyleneglycol, or mixtures thereof. However, it can also be preferred that no solvents or instead small quantities thereof are present in the metal paste in addition to the aliphatic hydrocarbons. For example, it can be advantageous that the portion of additional solvents in the metal paste is at maximum 10 weight percent, more preferably maximum 5 weight percent, even more preferably maximum 3 weight percent, and particularly preferred maximum 1 weight percent. According to a further preferred embodiment, the portion of aliphatic hydrocarbons, relative to the total weight of aliphatic hydrocarbons and further solvents, lies in the range of 30-100 weight percent, more preferably in the range of 50-100 weight percent, even more preferably in the range of 70-100 weight percent, and particularly preferably in the range of 80-100 weight percent.

Furthermore, the paste can contain at least one polymer to give the paste the desired characteristics. On the other hand, it can however be advantageous that the paste does not contain polymers or the portion thereof is small, since polymers, especially duroplasts, usually burn out at temperatures of more than 250° C. and thus have a disadvantageous effect on the sinterability of the paste. This is particularly true for duroplasts or pre-products thereof. Pre-products of duroplasts refer to compounds that can harden to duroplasts in the presence of further paste components. These duroplasts or pre-products thereof usually have a weight average molecular weight of less than 700. According to a preferred embodiment, the portion of polymers, which have a weight average molecular weight of less than 700, is not more than 6 weight percent relative to the total weight of the paste.

In addition, further substances of content, as for example common dispersing agents, tensides, defoamers, bonding agents, or viscosity-regulating agents, can be contained in the metal paste.

The previously described pastes can be used according to the invention for fastening an electronic component on a substrate. This fastening is preferably realized by sintering. According to the invention, sintering is understood to be the bonding of two or more components by heating while bypassing the fluid phase.

An electronic component is generally understood as an object, which can be part of an electronic assembly. According to a preferred embodiment, this is understood to be an individual part that cannot be further disassembled and that can serve as component of an electronic circuit. The electronic component can optionally comprise a unit of multiple component parts. The electronic component can, for example, be an active component or a passive component. According to particular embodiments, the electronic components are used in high-performance electronics.

According to a preferred embodiment, the electronic component is selected from the group consisting of diodes (for examples LEDs, Light Emitting Diodes), transistors (for example IGBTs, Insulated-Gate Bipolar Transistors, bipolar transistors with insulated gate electrode), integrated circuits, semiconductor chips, naked chips (Dies), resistors, sensors, condensers, coils, and cooling bodies.

By substrate is generally understood an object which can be connected to an electronic component. According to a preferred embodiment, the substrate is selected from the group consisting of lead frames, DCB-substrates (Direct-Copper-Bonded substrates) and ceramic substrates.

According to a preferred embodiment, the following pairs of electronic component and substrate are fastened to each other: LED/lead frame, LED/ceramic substrate, Die/lead frame, Die/ceramic substrate, Die/DCB-substrate, diode/lead frame, diode/ceramic substrate, diode/DCB-substrate, IGBT/lead frame, IGBT/ceramic substrate, IGBT/DCB-substrate, integrated circuit/lead frame, integrated circuit/ceramic substrate, integrated circuit/DCB-substrate, sensor/lead frame, sensor/ceramic substrate, cooling body (preferably copper or aluminum cooling body)/DCB, cooling body (preferably copper or aluminum cooling body)/ceramic substrate, cooling body/lead frame, condenser (preferably tantalum condenser, more preferably in non-housed condition)/lead frame.

According to a further preferred embodiment, multiple electronic components can be connected to the substrate. It can be further preferred that electronic components are located on opposite sides of the substrate.

Furthermore, electronic component, substrate or electronic component and substrate can comprise at least one metallization layer. This metallization layer can, for example, have pure metal or a metal alloy. If the metallization layer comprises a metal, this is then preferably selected from the group consisting of copper, silver, gold, palladium, and platinum. If the metallization layer comprises a metal alloy, this then preferably contains at least one metal selected from the group consisting of silver, gold, nickel, palladium, and platinum. The metallization layer can also have a multilayered construction. According to a further preferred embodiment, the metallization layer also contains a glass.

According to the invention, the electronic component is fastened on the substrate by sintering. In this connection “on” simply means that a surface of the electronic component is connected to a surface of the substrate, wherein it does not depend on the relative position of the electronic component, of the substrate or of the arrangement.

According to the invention, the electronic component and the substrate are brought into contact with one another for the purpose of sintering. The contacting thereby takes place via the paste according to the invention. According to a preferred embodiment, both the electronic component and substrate have a metallization layer, wherein the metallization layer of the electronic component and the metallization layer of the substrate are in contact with one another via the paste. According to the invention, a sandwich arrangement is initially created that has the electronic component, the substrate and a layer located in between that contains the paste according to the invention. A sandwich arrangement is preferably understood to be an arrangement in which the electronic component is located above the substrate or the substrate above the electronic component, and wherein the electronic component and substrate are essentially arranged parallel to one another.

The sandwich arrangement composed of the electronic component, the substrate and the paste lying in between can be manufactured according to a known prior art process. Preferably at least one surface of the substrate, preferably a surface of the substrate provided with a metallization layer, is initially equipped with the paste according to the invention. The paste can be applied to the surface of the substrate by conventional processes. The paste is preferably applied by a pressing process, for example screen printing or stencil printing. On the other hand, the paste can be applied by dispensing technology, by spraying technology, by pin transfer, or by dipping. Subsequently, the electronic component is placed with one of its surfaces, preferably with a surface that has a metallization layer, to the paste which has been applied on the surface of the substrate. Consequently, a paste layer is located between the substrate and the electronic component, preferably between the metallization layer of the substrate and the metallization layer of the electronic component.

The wet layer density between substrate and electronic component lies preferably in the range of 20-200 μm. Wet layer density is preferably understood as the distance between the opposite surfaces of substrate and electronic component. The preferred wet layer density depends on the selected process to apply the metal paste. If the metal paste is applied, for example, by screen printing, the wet layer density can preferably be 20-50 μm. If the metal paste is applied by stencil printing, then the preferred wet layer density can lie in the range of 50-200 μm.

According to a preferred embodiment, a drying step is performed prior to the sintering process. Drying is preferably understood as a reduction in the portion of solvent in the metal paste. According to a preferred embodiment, the portion of solvent in the metal paste after drying lies in the range of 1-5 weight percent, relative to the weight of the dried metal paste.

On the one hand, the drying can take place after manufacturing the sandwich arrangement. On the other hand, the drying can also take place immediately following the application of the paste on the at least one surface of substrate or electronic component, and prior to contacting with the electronic component or substrate to be connected. The drying temperature preferably lies in the range of 50-100° C. It is obvious that the drying time depends on the respective composition of the paste and the size of the sandwich arrangement to be sintered. However, common drying times lie in the range of 5-45 minutes.

The sandwich arrangement of the electronic component, the substrate and the layer arranged in between, which contains the paste according to the invention, is finally subjected to a sintering process. This sintering process is a low-temperature sintering process. According to the invention, a low-temperature sintering process is understood as a sintering process that preferably runs at a temperature of below 250° C., more preferably at a temperature of below 220° C., even more preferably at a temperature of below 200° C., and particularly preferably at a temperature of below 180° C.

The process pressure during sintering is preferably below 30 MPa, more preferably below 5 MPa and even more preferably below 1 MPa. Based on the use of the paste according to the invention, the sintering succeeds even without any use of process pressure, thus at a process pressure of 0 MPa.

The sintering time depends on the process pressure and preferably lies in the range of 2-45 minutes.

According to the invention, the sintering process can take place in an atmosphere that is not further restricted. Preferably, the sintering is carried out in an atmosphere that contains oxygen.

The sintering is carried out in a conventional apparatus suitable for sintering, in which the previously described process parameters can preferably be set.

The invention is hereinafter explained in detail based on the following examples, which should, however, not be understood as being limiting.

### EXAMPLES

### Example 1

A metal paste according to the invention, paste 1, was manufactured in which 83 weight percent of silver particles, present in the form of flakes and coated with stearic acid, and 17 weight percent Isopar M™, a petroleum distillate, consisting mainly of isoparaffins having 12-15 carbon atoms, were mixed to a homogenous paste.

Deposits of paste 1 having a density of 50 μm were pressed onto a DCB (Direct Copper Bonded) substrate, which were afterwards loaded with IGBT (Insulated-Gate Bipolar Transistor) chips having a base surface of 100 mm², to create a sandwich arrangement of substrate, paste 1 and chip. This sandwich arrangement was dried at a temperature of 100° C. for 5 minutes in a recirculating air drying cabinet.

The dried sandwich arrangement was finally sintered at a temperature of 200° C. and a pressure of 10 MPa for a period of 2 minutes.

This experiment was performed multiple times under the same conditions.

### Comparison Example 1

A comparison paste, comparison paste 1, was manufactured in which 83 weight percent of silver particles, present in the form of flakes and coated with stearic acid, 9 weight percent terpineol, and 8 weight percent tridecanol were mixed to a homogenous paste.

Deposits of comparison paste 1 having a density of 50 μm were pressed onto a DCB (Direct Copper Bonded) substrate, which were afterwards loaded with IGBT (Insulated-Gate Bipolar Transistor) chips having a base surface of 100 mm², to create a sandwich arrangement of substrate, comparison paste 1 and chip. This sandwich arrangement was dried at a temperature of 100° C. for 5 minutes in the recirculating air drying cabinet.

The dried sandwich arrangement was finally sintered at a temperature of 200° C. and a pressure of 10 MPa for a period of 2 minutes.

This experiment was performed multiple times under the same conditions.

### Comparison of the Contact Layers Contained in Example 1 and Comparison Example 1

The reliability of the contact layers contained in Example 1 and Comparison Example 1, respectively, between substrate and chip were determined by a peel test (described in Mertens, Christian: “The Low-Temperature Bonding Technique of Power Electronics,” Progress Report VDI Series 21, No. 365, Chapter 4.2, Dusseldorf, VDI Verlag (2004)). Here, it transpired that the contact layers obtained by use of paste 1 had significantly increased peel strength compared to the contact layers obtained by use of comparison paste 1. In particular, contact layers generated by use of paste 1 provided a uniform quality with respect to peel strength, compared to the contact layers generated by use of comparison paste 2.

### Example 2

A metal paste according to the invention, paste 2, was manufactured in which 83 weight percent of silver particles, present in the form of flakes and coated with stearic acid, 12 weight percent Exxsol™ D120, a mixture of hydrocarbons having 14-18 carbon atoms (predominantly n-alkanes, isoalkanes and cyclic hydrocarbons), and 5 weight percent silver carbonate were mixed to a homogenous paste.

Deposits of paste 2 having a density of 50 μm were pressed onto a DCB (Direct Copper Bonded) substrate, which was dried at a temperature of 75° C. for a period of 5 minutes and was afterwards loaded with a chip having a base surface of 10 mm² and a nickel-silver metallization, in order to create a sandwich arrangement of substrate, paste 2 and chip.

This sandwich arrangement was finally sintered at a temperature of 220° C. for a period of 15 minutes.

This experiment was performed multiple times under the same conditions.

### Comparison Example 2

A comparison paste, comparison paste 2, was manufactured in which 83 weight percent of silver particles, present in the form of flakes and coated with stearic acid, 12 weight percent terpineol and 5 weight percent silver carbonate were mixed to a homogenous paste.

Deposits of comparison paste 2 having a density of 50 μm were pressed onto a DCB (Direct Copper Bonded) substrate, which was dried at a temperature of 75° C. for a period of 5 minutes and was afterwards loaded with a chip having a base surface of 10 mm² and a nickel-silver metallization, in order to create a sandwich arrangement of substrate, comparison paste 2 and chip.

This sandwich arrangement was finally sintered at a temperature of 220° C. for a period of 15 minutes.

This experiment was performed multiple times under the same conditions.

### Comparison of the Contact Layers Contained in Example 2 and Comparison Example 2

The peel strength of the contact layers obtained in Example 2 and Comparison Example 2, respectively, between substrate and chip were determined by a conventional peel test. Here, it transpired that the contact layers obtained by use of paste 2 showed about 50% higher peel strength compared to the contact layers obtained by use of comparison paste 2. The peel tests with the arrangements obtained in Example 2 partially lead even to chip fracture, i.e., the chip was so strongly bonded to the substrate that removing it was only possible by destroying the chip. In particular, contact layers were generated by use of paste 2 which had a uniform quality with respect to peel strength, compared to the contact layers generated by use of comparison paste 2.

### Example 3

A metal paste according to the invention, paste 3, was manufactured in which 83 weight percent of silver particles, present in the form of flakes and coated with stearic acid, 7 weight percent Exxsol™ D120, a mixture of hydrocarbons having 14-18 carbon atoms (predominantly n-alkanes, isoalkanes and cyclic hydrocarbons), 5 weight percent silver carbonate, and 5 weight percent dicumylperoxide were mixed to a homogenous paste.

Deposits of paste 3 having a density of 50 μm were pressed onto a DCB (Direct Copper Bonded) substrate, which was dried at a temperature of 75° C. for a period of 5 minutes and was afterwards loaded with a chip having a base surface of 10 mm² and a nickel-silver metallization, in order to create a sandwich arrangement of substrate, paste 3 and chip.

This sandwich arrangement was finally sintered at temperature of 200° C. for a period of 15 minutes.

This experiment was performed multiple times under the same conditions.

### Comparison Example 3

A comparison paste, comparison paste 3, was manufactured in which 83 weight percent of silver particles, present in the form of flakes and coated with stearic acid, 7 weight percent terpineol, 5 weight percent silver carbonate, and 5 weight percent dicumylperoxide were mixed to a homogenous paste.

Deposits of comparison paste 3 having a density of 50 μm were pressed onto a DCB (Direct Copper Bonded) substrate, which was dried at a temperature of 75° C. for a period of 5 minutes and was afterwards loaded with a chip with a ground surface of 10 mm² and a nickel-silver metallization, in order to create a sandwich arrangement from substrate, comparison paste 3 and chip.

This sandwich arrangement was finally sintered at temperature of 200° C. for a period of 15 minutes.

This experiment was performed multiple times under the same conditions.

### Comparison of the Contact Layers Obtained in Example 3 and Comparison Example 3

The peel strength of the contact layers obtained in Example 3 and Comparison Example 3, respectively, between substrate and chip were determined by a conventional peel test. Here, it transpired that the contact layers obtained by use of paste 3 showed about 50% higher peel strength compared to the contact layers obtained by use of comparison paste 3. The peel tests with the arrangements obtained in Example 3 mostly led even to chip fracture, i.e., the chip was so strongly bonded with the substrate that removing it was only possible by destroying the chip. In particular, contact layers were generated by use of paste 3 which had a uniform quality with respect to peel strength, compared to the contact layers generated by use of comparison paste 3. Furthermore, paste 3 was clearly better processable compared to comparison paste 3.

### Example 4

A metal paste according to the invention, paste 4, was manufactured in which 83 weight percent of silver particles, present in the form of flakes and coated with stearic acid, 12 weight percent Exxsol™ D120, a mixture of hydrocarbons having 14-18 carbon atoms (predominantly n-alkanes, isoalkanes and cyclic hydrocarbons), and 5 weight percent aluminum formate were mixed to a homogenous paste.

Deposits of paste 4 having a density of 50 μm were pressed onto a DCB (Direct Copper Bonded) substrate, which was dried at a temperature of 75° C. for a period of 5 minutes and was afterwards loaded with a chip having a base surface of 10 mm² and a nickel-silver metallization, in order to create a sandwich arrangement of substrate, paste 4 and chip.

This sandwich arrangement was finally sintered at temperature of 220° C. for a period of 15 minutes.

This experiment was performed multiple times under the same conditions.

### Comparison Example 4

A comparison paste, comparison paste 4, was manufactured in which 83 weight percent of silver particles, present in the form of flakes and coated with stearic acid, 12 weight percent terpineol, and 5 weight percent aluminum formate were mixed to a homogenous paste.

Deposits of comparison paste 4 having a density of 50 μm were pressed onto a DCB (Direct Copper Bonded) substrate, which was dried at a temperature of 75° C. for a period of 5 minutes and was afterwards loaded with a chip having a base surface of 10 mm² and a nickel-silver metallization, in order to create a sandwich arrangement of substrate, comparison paste 4 and chip.

This sandwich arrangement was finally sintered at temperature of 220° C. for a period of 15 minutes.

This experiment was performed multiple times under the same conditions.

### Comparison of the Contact Layers Obtained in Example 4 and Comparison Example 4

The peel strength of the contact layers obtained in Example 4 and Comparison Example 4, respectively, between substrate and chip were determined by a conventional peel test. Here, it transpired that the contact layers obtained by use of paste 4 showed about 50 to 70% higher peel strength, compared to the contact layers obtained by use of comparison paste 4. The peel tests with the arrangements obtained in Example 4 partially led even to chip fracture, i.e., the chip was so strongly bonded with the substrate that removing it was only possible by destroying the chip. In particular, contact layers were generated by use of paste 4 which had a uniform quality with respect to peel strength, compared to the contact layers generated by use of comparison paste 4.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

I/we claim:

1. A paste comprising (a) metal particles having a coating, the coating comprising at least one coating compound selected from the group consisting of fatty acids, fatty acid salts and fatty acid esters, and (b) at least one aliphatic hydrocarbon compound.

2. The paste according to claim 1, wherein the metal particles are silver particles.

3. The paste according to claim 1, wherein the metal particles are present as flakes.

4. The paste according to claim 1, wherein the at least one coating compound is selected from the group consisting of saturated fatty acids having 8-28 carbon atoms, salts of saturated fatty acids having 8-28 carbon atoms, esters of saturated fatty acids having 8-28 carbon atoms, and mixtures thereof.

5. The paste according to claim 1, wherein the at least one aliphatic hydrocarbon compound is selected from the group consisting of saturated hydrocarbons represented by the formulas: CₙH₂ₙ₊₂, CₙH₂ₙ and CₙH₂ₙ₋₂, where n is a whole number between 5 and 32.

6. The paste according to claim 1, wherein a ratio of the weight proportion of the at least one coating compound selected from the group consisting of fatty acids, fatty acid salts and fatty acid esters, to the weight proportion of the at least one aliphatic hydrocarbon compound lies in a range of 0.001-1.0.

7. The paste according to claim 1, wherein a ratio of the carbon atoms contained in a main chain of a main component of the coating, to the carbon atoms contained in a main chain of a main component of the at least one aliphatic hydrocarbon compound lies in a range of 0.5-2.0.

8. The paste according to claim 1, wherein a proportion of metal particles relative to a total weight of the paste lies in a range of 75-90 weight percent.

9. The paste according to claim 1, wherein a proportion of the at least one coating compound relative to a total weight of the paste lies in a range of 0.05-2.5 weight percent.

10. The paste according to claim 1, wherein a proportion of the at least one aliphatic hydrocarbon compound relative to a total weight of the paste lies in a range of 3-25 weight percent.

11. The paste according to claim 1, wherein a proportion of polymers having a weight average molecular weight of less than 700 is not more than 6 weight percent relative to a total weight of the paste.

12. A sandwich assembly for electronics, comprising an electronic component fastened on a substrate by the paste according to claim 1, wherein the paste is located between the electronic component and the substrate.

13. A process for fastening an electronic component on a substrate, the process comprising:
(i) providing an electronic component and a substrate;
(ii) creating a sandwich arrangement having the electronic component, the substrate and a layer arranged in between them, the layer comprising a paste comprising (a) metal particles having a coating, the coating comprising at least one coating compound selected from the group consisting of fatty acids, fatty acid salts and fatty acid esters, and (b) at least one aliphatic hydrocarbon compound; and
(iii) sintering the sandwich arrangement.
